(19) United States
(12) Patent Application Publication
(10) Pub. No.: US 2010/0251789 A1
(43) Pub. Date: Oct. 7, 2010

(54) Global Warming Mitigation Method

(76) Inventor: James Russell Baird, Nanaimo (CA)

Correspondence Address: James Russell Baird, 201 3087 Barons Rd., Nanaimo, BC, V9T 3Y6, CA

(21) Appl. No.: 12/408,656

(22) Filed: Mar. 20, 2009

(51) Int. Cl. E02B 13/00; G06Q 90/00; H02K 7/18; F03D 9/00; H01L 35/00; B01D 53/62; C05F 11/00

(52) U.S. Cl. 71/23; 405/52; 705/500; 290/1 R; 290/55; 136/201; 435/266

(57) ABSTRACT

The present invention provides a method of sequestering carbon dioxide and water in a desert environment. In a first step heat that would otherwise cause thermal expansion of the ocean and resultant sea level rise is extracted to produce energy. A portion of the energy is used to desalinate seawater. The desalinate water is pumped into a desert environment and vegetation is planted in the irrigated desert portion. The vegetation sequesters carbon dioxide. The seawater extracted for desalination further reduces sea level rise. Irrigation water moderates the day and nighttime temperature fluctuations of hot deserts. Lowering the daytime temperature increases the deserts potential to sequester water. The commercial and arable potential of the desert is augmented by the enrichment of its soil by composted vegetation, its irrigation and the moderation of its diurnal temperature fluctuations.

### BACKGROUND OF THE INVENTION

1. Field of the Invention

The present invention relates generally to the mitigation of the principal cause and forecasted effects of global warming. More particularly, the present invention relates to a method of conversion of ocean heat to productive energy and to sequestering carbon dioxide (CO.sub.2) and water in a desert environment.

2. Description of the Prior Art

Use of the Earth's resources has resulted in global scale environmental problems including elevated atmospheric CO.SUB.2 concentrations and rising sea levels As a result of land use change and the burning of fossil fuels, atmospheric CO.sub.2 levels are predicted to double in as little as 60 years. It is expected that elevated atmospheric concentrations of CO.sub.2 and other greenhouse gases will facilitate greater storage of heat within the atmosphere leading to enhanced surface temperatures and rapid climate change. The impact of unmitigated climate change will likely be economically expensive and environmentally hazardous. One of the most threatening outcomes of unmitigated climate change predicted over the course of the next century is sea level rise of between 90 to 880 mm, with a central value of 480 mm. The water currently held in the world's glaciers is melting and a rise in the Earth's surface temperature is expected to accelerate the process. The melted water flows into the Earth's oceans and, in conjunction with thermal expansion of the oceans due to the rising temperature, raises their levels.

Reducing potential risks of climate change will require sequestration of atmospheric CO.sub.2, conversion of a portion of the increasing thermal load being taken up by the oceans to other forms of energy, and/or the terrestrial taking up of much of the water that would otherwise raise the level of the oceans and inundate populated coastal areas.

Methods proposed to capture and store atmospheric CO.sub.2 include storage in geological formations, injection into the deep ocean, and uptake by phytoplankton via fertilization of the ocean. The limited capacity and duration, expense, and environmental outcomes of these methods are largely unresolved and may prohibit their utility.

The most economically and environmentally plausible manner to sequester atmospheric CO.sub.2 is to enhance natural sinks. Natural options avoid the costs associated with industrial separation, capture, compression, and storage of CO.SUB.2, and reduce potential negative environmental side effects. Natural methods offer reservoirs of large capacity and the ability to replace the carbon from whence it came, the long-term carbon cycle. Enhancing forest growth is an example of a natural method of carbon sequestration that is environmentally benign and, with proper management, allows for the value-added option of sustainable forest harvesting. Many present day activities would have to be disrupted however to return farmlands to forests or wetlands which would increase carbon sequestration. For example loss of farmlands will decrease crop production for food and biofuels.

The largest natural carbon reservoirs include ocean waters and marine sediments. Dissolving CO.SUB.2 in seawater however increases the hydrogen concentration in the ocean, and thus its acidification. This acidification has negative consequences for oceanic calcifying organisms and may hamper their ability to take up CO.SUB.2.

Deserts are dry regions of the planet with sparse vegetation and equally sparse commercial activity. They take up about one third of the Earth's land surface. Roughly two thirds of this is made up of the Antarctic Desert and the Arctic, which due to their cold climate and negligible vegetation have limited capacity to sequester atmospheric CO.sub.2. The other third are hot deserts, which can be irrigated to facilitate the production of value-added crops for food, fuel, and fibre or to produce building materials. These crops would sequester significant quantities of CO.SUB.2.

Deserts can also take up much of the water from melting glaciers that would otherwise add to sea level rise.

An effective method of CO.SUB.2 and water sequestration would be to promote the reclamation of the world's hot deserts to arable use. Accordingly, there is a need in the art to develop methods of promoting this conversion for the purposes of CO.SUB.2 and water sequestration.

An effective method of utilizing the heat the oceans are absorbing, causing thermal expansion and sea level rise, would be to convert this heat to more productive energy forms. Accordingly, there is a need in the art to develop methods of promoting this conversion of heat to more productive forms of energy for the purpose of limiting sea level rise.

### SUMMARY OF THE INVENTION

The present invention is concerned with sequestering CO.SUB.2 and water, and, more specifically, to a method of sequestering CO.SUB.2 and water in a desert environment. Another concern is the maintenance of sea levels near current levels to prevent inundation of inhabited coastal areas, more specifically, to a method to convert the heat causing thermal expansion of the oceans to a more productive form of energy.

An objective of the present invention is to provide a viable, economic and commercial means of stabilizing the level of the world's oceans to prevent inundation of many of the world's populated coastal cities.

Another objective of the present invention is to provide a viable, economic and commercial means of curbing the CO.SUB.2 build up in the atmosphere, which is believed to be contributing to global climate change.

In some embodiments of this invention ocean energy is harnessed.

In some embodiments of this invention energy, in the form of heat, is removed from the ocean to reduce thermal expansion of the oceans.

In some embodiments of this invention solar energy is harnessed.

In some embodiments of this invention wind energy is harnessed.

Another object of this invention is to use carbon free, renewable energy sources to desalinate ocean water.

Another object of this invention is to use carbon free, renewable energy sources to pump water into a desert

Another objective of this invention is to grow commercial products in the Earth's hot deserts.

Another objective of this invention is to convert the hot deserts to economically viable carbon sinks.

Another objective of this invention is to enrich hot desert soil by composting none commercial vegetable matter.

Another objective of this invention is to provide a sustainable environment for some of the world's poorest populated areas.

Another object of this invention is to moderate the temperature fluctuations in the desert that sustain its desiccation.

The novel features which are considered characteristic for the invention are set forth in the appended claims. The invention itself, however, both as to its construction and as to its method of operation, together with additional objects and advantages thereof, will be best understood from the following description of the specific embodiments when read and understood in connection with the accompanying drawings. Attention is called to the fact, however, that the drawings are illustrative only, and that changes may be made in the specific construction illustrated and described within the scope of the appended claims.

Other objects and advantages of the present invention will be apparent upon consideration of the following specification, with reference to the accompanying drawings in which like numerals correspond to like parts shown in the drawings.

### BRIEF DESCRIPTION OF THE DRAWINGS

FIG. 1 depicts the oceans and seas of the world.

FIG. 2 depicts the greenhouse effect.

FIG. 3 depicts the processes that are projected to induce global sea level rise.

FIG. 4 depicts sea level rise.

FIG. 5 depicts the major hot deserts of the world.

FIG. 6 is a map of the annual pan rates of evaporation in (inches) across the United States.

FIG. 7 is a schematic of the Ocean Thermal Energy Conversion method.

FIG. 8 depicts floating wind turbine concepts with differing types of moorings.

FIG. 9 depicts solar thermal energy.

FIG. 10 depicts a seawater desalination concept using reverse osmosis.

FIG. 11 depicts a typical center-pivot irrigation system.

FIG. 12 depicts the process of photosynthesis.

FIG. 13 depicts the anaerobic and aerobic processes of decomposition.

FIG. 14 (a) is a representation of the Earth's land surface temperature variations and FIG. 14 (b) is a representation of the Earth's corresponding vegetation.

### DESCRIPTION OF THE PREFERRED EMBODIMENT

In respect of the following and previously set out description and explanation, it should be understood that while the information given is considered to be correct, such explanations are necessarily somewhat speculative due to the complexity of natural systems and direct field measurement of CO.sub.2 sequestration is difficult as tools currently employed are to varying degrees operationally and theoretically limited. Applicant would not want to be bound, therefore, by the following if, subsequently, new and better information becomes available. The explanations hereinafter given are made for the purpose of full and complete disclosure of the invention but the qualification given above should be borne in mind.

The following description generally relates to systems and methods for sequestering water and CO.sub.2 in a desert environment. Such an environment may be treated to yield relatively high value commercial and sustaining food products.

The present invention significantly improves on the methodologies for sequestering CO.SUB.2 and provides a method of sequestering a portion of the water from glacial runoff believed to be caused by global warming that would otherwise contribute to sea level rise. It also converts to energy a portion of the heat being transferred to the world's oceans that would otherwise cause thermal expansion.

In this specification the following terms shall have the following meanings. The term “albedo” shall mean the extent to which an object diffusely reflects light from the Sun. The term “equilibrium line altitude” shall mean the point above which, or poleward of which, snow and ice cover the ground throughout the year. The term “evapotranspiration” shall mean the sum of evaporation and plant transpiration from the earth's land surface to the atmosphere. The term “firn” shall mean partially compacted névé that has been left over from past seasons and has been recrystallized into a substance denser than névé, where névé is a young, granular type of snow which has been partially melted, refrozen and compacted. The term “glacial mass balance” shall mean the difference between accumulation and ablation (melting and sublimation) of a glacier. The term “geoengineering” shall mean the application of technology to tackle human-induced climate change by either removing carbon dioxide from the atmosphere or by managing solar radiation in order to negate the net warming effect of climate change. The term “ice-albedo feedback” shall mean the positive feedback mechanism whereby ice and snow reflect incoming short wave radiation from the sun causing the reflecting surface to cool, which in turn may cause more ice to form increasing the surface albedo even more. The term “planetary engineering” shall mean the application of technology for the purpose of influencing the global properties of a planet to make it habitable for life. The term “radiative forcing” shall mean the change in net irradiance at the tropopause. Where “Net irradiance” is the difference between the incoming radiation energy and the outgoing radiation energy in a given climate system and the tropopause is the boundary in the atmosphere between the troposphere and the stratosphere. Going upward from the surface, it is the point where air ceases to cool with height, and becomes almost completely dry. The term “thermal expansion” shall mean the tendency of matter to change in volume in response to a change in temperature.

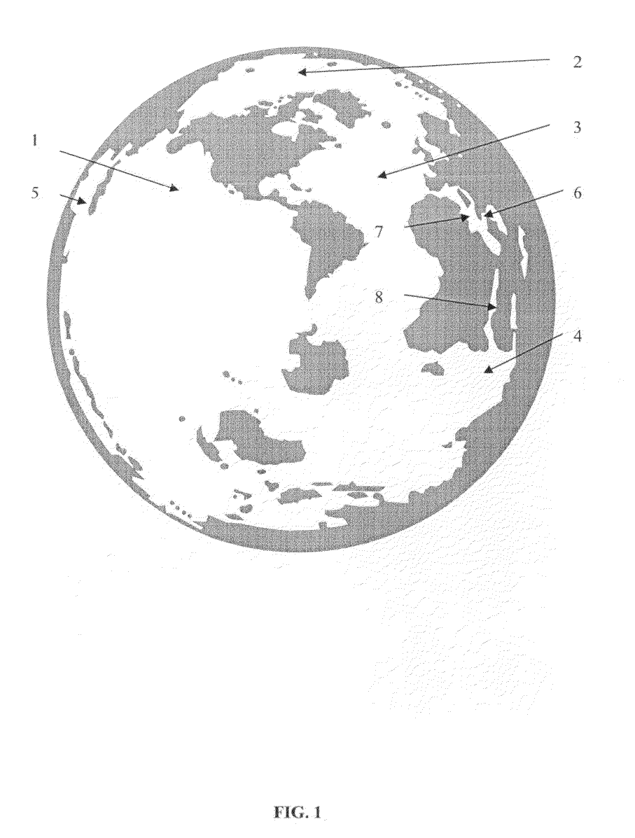

In FIG. 1 the oceans and seas of the world are depicted.

The Pacific Ocean 1, the Arctic Ocean 2, the Atlantic Ocean 3, the Indian Ocean 4, the South China Sea 5, the Black Sea 6 the Mediterranean Sea 7, and the Red Sea 8 cover approximately 71% of the Earth's surface, an area of approximately 361 million square kilometres.

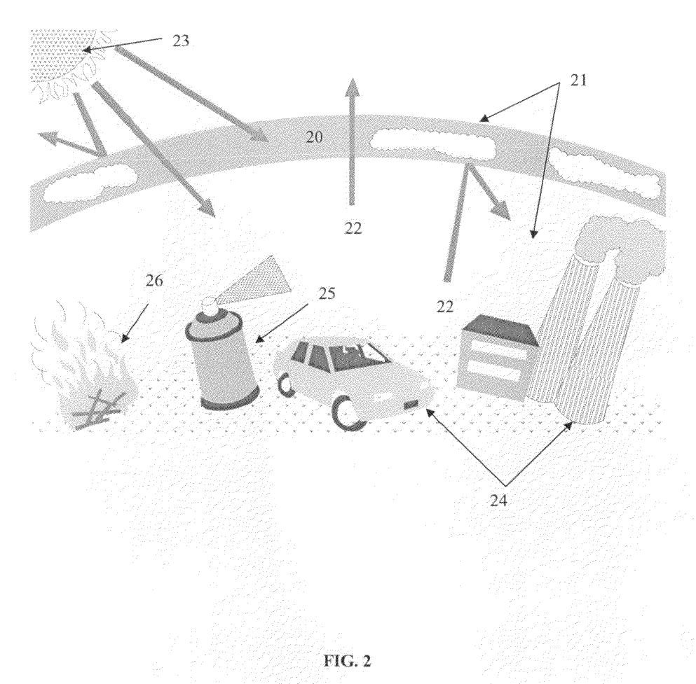

FIG. 2 depicts the greenhouse effect

In the 1980s scientists determined the average temperature of the Earth's surface was slowly rising. This trend is referred to as global warming. There has emerged a broad scientific consensus the cause of this rise is a build up of gases 20 in the atmosphere 21.

A greenhouse is a glass house in which plants grow which lets light in and at the same time keeps heat from getting out. This heat keeps the plants warm, even when it is cold outside.

It is believed the same thing is happening with the Earth's atmosphere 21. It lets sunlight 23 in and CO.SUB.2 and other gases 20 restrict this heat 22 from escaping into space.

Anthropogenic factors are human activities that change the environment. Various hypotheses for human-induced climate change have been argued for many years though, generally, the scientific debate has evolved from skepticism to a scientific consensus that human activity is the probable cause for the rapid changes in world climate in the past several decades. Consequently, the debate has largely shifted onto ways to reduce further human impact and to find ways to adapt to change that has already occurred.

Of most concern in these anthropogenic factors is the increase of CO.SUB.2 levels due to emissions from fossil fuel 24 combustion, followed by aerosols 25 (particulate matter in the atmosphere 21) and cement manufacture. Other factors, including land use, ozone depletion, animal agriculture and deforestation 26, are also of concern in the roles they play—both separately and in conjunction with other factors—in affecting climate change.

Human activities since the industrial revolution have increased the atmospheric concentration of various greenhouse gases 20, leading to increased radiative forcing from CO.SUB.2, methane, tropospheric ozone, CFCs and nitrous oxide. The atmospheric concentrations of CO.SUB.2 and methane have increased by 36% and 148% respectively since the beginning of the industrial revolution in the mid-1700s. These levels are considerably higher than at any time during the last 650,000 years, the period for which reliable data has been extracted from ice cores. Less direct geological evidence indicates that CO.SUB.2 values this high were last seen approximately 20 million years ago. Fossil fuel 24 burning has produced approximately three-quarters of the increase in CO.SUB.2 from human activity over the past 20 years. Most of the rest is due to land-use change, in particular deforestation 26.

CO.SUB.2 concentrations are expected to continue to rise due to ongoing burning of fossil fuels 24 and land-use change. The rate of rise will depend on uncertain economic, sociological, technological, and natural developments.

Beginning with the industrial revolution in the 19th Century and accelerating since, the human consumption of fossil fuels 24 has elevated CO.SUB.2 levels from a concentration of approximately 280 parts per million (ppm) in pre-industrial times to around 387 ppm today. The concentrations are increasing at a rate of about 2-3 ppm/year. If current rates of emission continue, these increasing concentrations are projected to reach a range of between 535 to 983 ppm by the end of the 21st century. Along with rising methane levels, it is suggested that these changes may cause an increase of 1.4-5.6° C. between 1990 and 2100 Proposals by some scientists and international coalitions, aimed at attempting to prevent drastic climate change, have suggested setting goals to try to limit concentrations of CO.SUB.2 to a range of 450 to 500 ppm.

One alternative hypothesis, widely refuted, to the consensus view that anthropogenic factors are causing temperature increase is that recent warming may be the result of variations in solar activity.

Models are used to help investigate the causes of recent climate change by comparing the observed changes to those that the models project from various natural and human-derived causes. Although these models do not unambiguously attribute the warming that occurred from approximately 1910 to 1945 to either natural variation or human effects, they do suggest that the warming since 1975 is dominated by man-made greenhouse gas emissions.

The Northern Hemisphere has more land than the Southern Hemisphere, so it warms faster. The Northern Hemisphere also has extensive areas of seasonal snow and sea-ice cover subject to the ice-albedo feedback. More greenhouse gases 20 are emitted in the Northern than Southern Hemisphere, but this does not contribute to a difference in warming between the north and south because the major greenhouse gases 20 persist long enough to mix between the hemispheres.

Some economists have tried to estimate the aggregate net economic costs of damages from climate change across the globe. Such estimates have so far yielded no conclusive findings; in a survey of 100 estimates, the values ran from US$-3 per tonne of CO.SUB.2 up to US$95 per tonne of CO.SUB.2, with a mean of US$12 per tonne of CO.SUB.2.

One widely publicized report on potential economic impact is the 2006 Stern Review. The report said the costs of acting to counter climate change, by stabilizing emissions of carbon dioxide in the atmosphere 21, might be about 1 percent of annual global gross domestic product (GDP) by 2050. But the cost of doing nothing was found to be far greater—risking up to 20 percent of the world's wealth. The report's methodology, advocacy and conclusions have been criticized by many economists, primarily around the Review's assumptions of discounting and its choices of scenarios. Others have supported the general attempt to quantify economic risk, even if not the specific numbers.

In a 2009 update Lord Stern revised his 2006 prediction, saying the cost of inaction would be “50 percent or more higher” than his previous highest estimate—meaning it could cost a third of the world's wealth.

The International Panel on Climate Change (IPCC) Working Group is responsible for crafting reports that deal with the mitigation of global warming and analyzing the costs and benefits of different approaches. The 2007 IPCC Fourth Assessment Report concluded that no one technology or sector can be completely responsible for mitigating future warming. They find there are key practices and technologies in various sectors, such as energy supply, transportation, industry, and agriculture that should be implemented to reduce global emissions. They estimate that stabilization of CO.SUB.2 equivalent between 445 and 710 ppm by 2030 will result in between a 0.6 percent increase and three percent decrease in global GDP.

For the purpose of this invention the 1 percent global GDP decrease suggested by the Stern Review is used for comparative purposes.

According to the IPCC Working Group, to limit temperature rise to 2 degrees Celsius, developed countries as a group would need to reduce their emissions to below 1990 levels in 2020 (on the order of −10 percent to 40 percent below 1990 levels for most of the considered regimes) and to still lower levels by 2050 (80 percent to 95 percent below 1990 levels), even if developing countries make substantial reductions.

Human nature what it is, changing current energy regimes and reducing man's detrimental impacts on the environment will be difficult if not impossible to achieve. It is an objective of the current invention therefore to reduce the human impact of CO.SUB.2 on climate change, whether or not energy regimes are changed or other impacts are lessened. In one aspect of the current invention substantial amounts of the greenhouse gas CO.SUB.2 will be sequestered in vegetation planted in irrigated deserts.

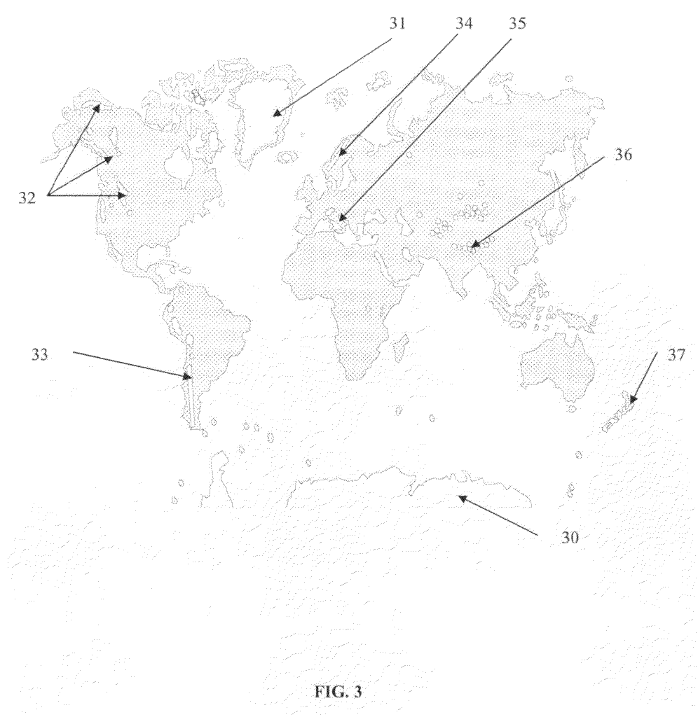

FIG. 3 depicts the major ice caps and glaciers of the world.

Glacial ice covers 10-11 percent of all land. The majority, almost 90 percent, of Earth's ice mass is in Antarctica 30, while the Greenland 31 ice cap contains 10 percent of the total global ice mass. Minor glaciers are found in North America 32 in the Arctic, and the Coastal and Rocky Mountain ranges. In South America 33 minor glaciers are found in the Andes while in Europe they are found in the Scandinavian countries 34 and the Alps 35. The Himalayan Mountains 36 and Southern Alps of New Zealand 37 comprise the remainder of the Earth's minor glaciers.

According to the National Snow and Ice Data Centre (NSIDC) in Boulder, Colo., if all glaciers melted today the seas would rise about 70 meters (m).

During the last ice age (when glaciers covered more land area than today) the sea level was about 122 m lower than it is today. At that time, glaciers covered almost one-third of the land.

During the last warm spell, 125,000 years ago, the seas were about 5.5 m higher than they are today. About three million years ago the seas could have been up to 50.3 m higher.

Sparse records indicate that glaciers have been retreating since the early 1800s. In the 1950s measurements began that allow the monitoring of glacial mass balance, reported to the World Glacier Monitoring Service (WGMS), Zurich, Switzerland, and the NSIDC. Although it is difficult to connect specific weather events to global warming, an increase in global temperatures may in turn cause broader changes, including glacial retreat, Arctic shrinkage, and worldwide sea level rise.

Glaciers around the globe continue to melt at high rates. Tentative figures for the year 2007, of the WGMS indicate a loss of average ice thickness of roughly 0.67 meter water equivalent (m w.e.), where the standardized unit m.w.e. takes the different densities of change measurements in ice, firn and snow into account. One meter of ice thickness corresponds to about 0.9 m w.e.

Some glaciers in the European Alps lost up to 2.5 m w.e. The new still tentative data of more than 80 glaciers confirm the global trend of fast ice loss since 1980. Glaciers with long-term observation series (30 glaciers in 9 mountain ranges) have experienced a reduction in total thickness of more than 11 m w.e. (12.2 metres) until 2007. The average annual ice loss during 1980-1999 was roughly 0.3 m w.e. per year. Since 2000, this rate has increased to about 0.7 m w.e. per year. The record loss during the two decades 1980-1999—0.7 metres in 1998—was exceeded in three of the six years between 2002 and 2007.

Table 1 is an estimate of the global distribution of water according to the Water resources, Encyclopedia of Climate and Weather, ed. by S. Schneider, Oxford University Press.

TABLE 1

| | Water volume, In | Percent of | Percent of |
|---|---|---|---|
| Water source | cubic kilometres | total water | total freshwater |
| Ice caps, Glaciers, & | 24,064,000 | 1.7% | 68.7% |
| Permanent Snow | | | |
| Total global | 35.030,000 | 2.5% | |
| freshwater | | | |
| Total global water | 1,386,000,000, | | |

Billions of people depend directly or indirectly on glaciers as natural water storage facilities for drinking water, agriculture, industry and power generation during key parts of the year.

It is an objective of the current invention to reduce the contribution CO.SUB.2 makes to glacier melting by sequestering a portion of this greenhouse gas in vegetation planted in irrigated portions of the world's deserts.

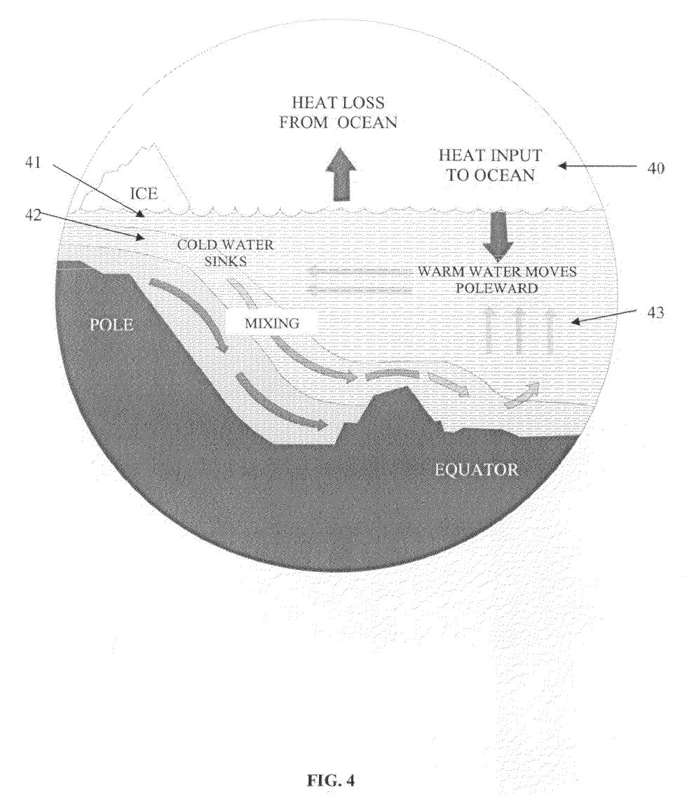

FIG. 4 depicts the processes that are projected to induce global sea level rise. Solar radiation 40 is absorbed by the oceans of the world and this heat 40 causes thermal expansion of the ocean water. The water melting from the glaciers and ice caps 41 of the world are causing additional sea level rise. The melting polar caps inject cold, heavy water 42 to the world's oceans, which sink and flow towards the equator where it is heated 43, rises and completes the cycle flowing back towards the poles.

Current sea level rise is occurring at a rate of around 1.8 mm per year for the past century, mainly it is widely believed as a result of human-induced global warming. This rate may be increasing. Measurements from the period 1993-2003 indicated a mean rate of 3.1 mm/year.

It is believed unmitigated global warming will continue to increase sea levels over at least the coming century. Increasing temperatures result in sea level rise by the thermal expansion of water and through the addition of water to the oceans from the melting of continental ice sheets.

There is no physical capacity of humans to protect against long-term sea level rise. Since greater than 75 percent of the human population lives within 60 km of a coast, it is important that sea level rise be limited to the greatest extent possible to minimize loss of life, and economic and ecological impacts.

Thermal expansion, which is well quantified, is currently the primary contributor to sea level rise and is expected to be the primary contributor over the course of the next century. Glacial contributions to sea level rise are believed to be less important, and are more difficult to predict and quantify.

Values for predicted sea level rise over the course of the next century typically range from 90 to 880 mm, with a central value of 480 mm. Based on an analog to the deglaciation of North America 9000 years ago, some scientists predict sea level rise of 1.3 m in this century. However, models of glacial flow in the smaller present-day ice sheets show that a probable maximum value for sea level rise in the next century is 800 mm, based on limitations on how quickly ice can flow below the equilibrium line altitude and to the sea.

For the purpose of this invention the 480 mm value or 0.48 m is used for comparative purposes.

A simple model to demonstrate sea level rise due to thermal expansion assumes that the ocean consists of two parts: the surface ocean and the deep ocean. The surface ocean is uniform in depth, temperature, and salinity. The depth of the surface ocean is 500 m. The average initial temperature of the upper ocean is 14° C. The deep ocean is everything else, and is assumed to not change.

The volume of water in the ocean is given by the equation: V=A*d, where A is the surface area of the ocean and d is the depth of the ocean. The mass of an object is equal to its volume multiplied by its density; m=V*ρ. Therefore d=m/(ρ*A). The problems is to find the changes in sea level Δd, which=d−d0, where d0 is the initial height of the ocean, 500 m.

Change in depth (sea level rise) is a function of density and the assumption for the purposes of this calculation is that the mass of the ocean and its surface area do not change. It is also assumed for the purposes of this calculation that the salinity of the ocean remains constant. The oceans density therefore is dependent solely on temperature. Since it has already been assumed the sea will rise by 0.48 m over this century, this equates to a 4.4° C. increase in the temperature of the ocean, which is the increase in ocean temperature used in other calculations in this application

Sea level rise will change the amount and pattern of precipitation, likely including an expanse of the subtropical desert regions. Other likely effects include Arctic shrinkage and resulting Arctic methane release, shrinkage of the Amazon rainforest, increases in the intensity of extreme weather events, changes in agricultural yields, modifications of trade routes, glacier retreat, species extinctions and changes in the ranges of disease vectors.

Sea temperatures increase more slowly than those on land both because of the larger effective heat capacity of the oceans and because the ocean can lose heat by evaporation more readily than the land.

Glacial isostatic adjustment (GIA) is causing some coastal lands to sink, increasing the rate of sea level rise for those areas. In some areas of the world, GIA is causing land to rise allowing for some compensation to rising sea level.

A 2008 study by a group of U.S. scientists found that the economic damages from hurricanes has increased in the U.S. over time due to greater population, infrastructure, and wealth on the U.S. coastlines, and not to any spike in the number or intensity of hurricanes.

They found that although some decades were quieter and less damaging in the U.S. and others had more land-falling hurricanes and more damage, the economic costs of land-falling hurricanes has steadily increased over time.

A paper published in Natural Hazards Review, found that economic hurricane damage in the U.S. has been doubling every 10 to 15 years because more and more people continue to move to the hurricane-prone coastlines. The researchers for this paper used two different methods, which gave similar results, to estimate the economic damages of historical hurricanes if they were to strike today. The first method utilized population increases at the county coastal level, while the second used changes in housing units at the county coastal level. Both methods used changes in inflation and wealth at the national level.

The results of their study indicates that if the 1926 Great Miami Hurricane were to hit today, it would cause the a loss of between $140 billion to $157 billion, compared to Hurricane Katrina, causing the second most damage at $81 billion.

The team concluded that potential damage from storms—currently about $10 billion yearly—is growing at a rate that may place severe burdens on exposed communities, and that avoiding huge losses will require a change in the rate of population growth in coastal areas, major improvements in construction standards, or other mitigation actions.

There are two types of inundation that will be caused by sea level rise: permanent inundation and episodic inundation.

A higher sea level will provide a higher base for storm surges. A one-meter rise in sea level would enable a 15-year storm to flood areas that today are only flooded by 100-year storms. Flood damages would increase 36-58% for a 30-cm rise in sea level and increase 102-200% for sea level rise greater than 90 cm. Larger storms cause loss of beach width and force large sediments into inlets.

Although the frequency of hurricanes may not be increasing due to global warming it is clear rising sea levels will increase the damage they produce.

Rising sea levels would allow saltwater to penetrate farther inland and up streams. Higher salinity impairs both surface and groundwater supplies. This effect would impair water supplies, ecosystems, and coastal farmland. Saltwater intrusion would also harm aquatic plants and animals as well as threaten human water supply.

The penetration of saltwater can be compared to what occurs during extreme droughts when river runoff is diminished, forcing a fallow period in agriculture

In addition to damage to ecosystems, sea level rise promotes saltwater intrusion into coastal aquifers. A freshwater lens overlies saltwater along barrier coasts, and volcanic and coral islands. This freshwater lens is 40 times thicker than the elevation of the water table above mean sea level Therefore each increment of sea level rise reduces the freshwater capacity of the lens by 40 times.

It is an objective of the current invention to limit the expected threat from sea level rise by generating power from a portion of the heat that would otherwise induce thermal expansion in the oceans and to sequester desalinated ocean water, which would otherwise inundate populated areas and produce other hazardous environmental effects, in the world's arid deserts.

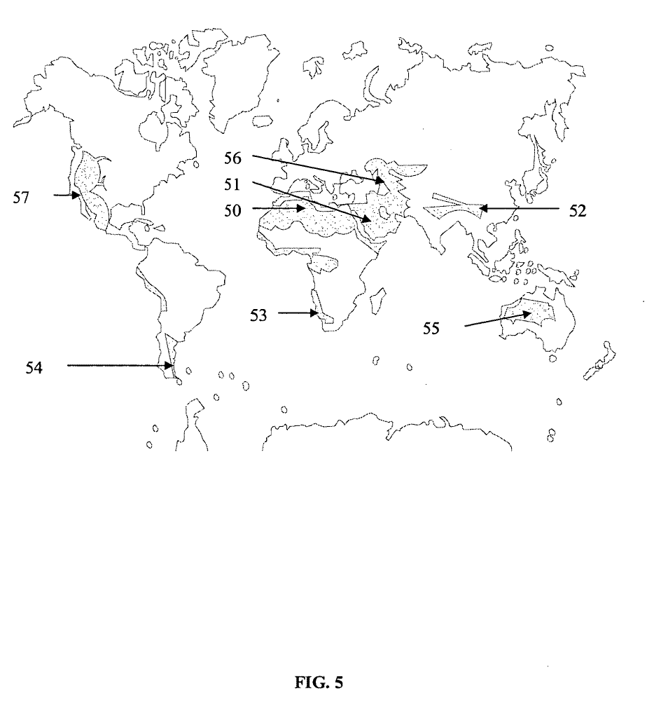

FIG. 5 depicts the major hot deserts of the world.

Deserts take up about one third of the Earth's land surface. One definition of a desert is an area that receives an average annual precipitation of less than 0.25 m or an area in which more water is lost to evaporation than falls as precipitation Hot deserts usually have a large diurnal and seasonal temperature range, with high daytime temperatures, and low night time temperatures (due to extremely low humidity). In hot deserts the temperature in the daytime can reach 45° C. or higher in the summer, and dip to 0° C. or lower in the winter. Water acts to trap infrared radiation from both the sun and the ground, and dry desert air is incapable of blocking sunlight during the day or trapping heat during the night. Thus, during daylight most of the sun's heat reaches the ground, and as soon as the sun sets the desert cools quickly by radiating its heat into space.

Table 2 shows the world's ten largest deserts.

TABLE 2

| Rank | Desert | Area (km²) | Cold | Hot | % of T |
|---|---|---|---|---|---|
| 1 | Antarctic Desert | 13,829,430 | 13,829,430 | | 32.10% |
| 2 | Arctic 2 | 13,700,000 | 13,700,000 | | 31.80% |
| 3 | Sahara (50) | 9,100,000 | | 9,100,000 | 21.12% |
| 4 | Arabian Desert (51) | 2,330,000 | | 2,330,000 | 5.41% |
| 5 | Gobi Desert (52) | 1,300,000 | | 1,300,000 | 3.02% |
| 6 | Kalahari Desert (53) | 900,000 | | 900,000 | 2.09% |
| 7 | Patagonian Desert (54) | 670,000 | | 670,000 | 1.55% |
| 8 | Great Victoria Desert (55) | 647,000 | | 647,000 | 1.50% |
| 9 | Syrian Desert (56) | 520,000 | | 520,000 | 1.21% |
| 10 | Great Basin Desert (57) | 92,000 | | 92,000 | 0.21% |
| Total | | 43,088,430 | 27,529,430 | 15,559,000 | 100.00% |

Many deserts are formed by rain shadows; mountains blocking the path of precipitation to the desert. Deserts are often composed of sand and rocky surfaces. Sand dunes called ergs and stony surfaces called hamada surfaces compose a minority of desert surfaces. Exposures of rocky terrain are typical, and reflect minimal soil development and sparseness of vegetation.

The ever worsening problems of environmental degradation, combined with increasing population makes action imperative to restore deserts to productive use. Agroforestry, irrigated agriculture, mixed species grazing, agri-tourism and other techniques can be used to increase yields and speed recovery. These approaches must also be sustainable.

The largest of the world's hot deserts is the Sahara 50 which was once verdant but turned to desert over thousands of years rather than in an abrupt shift as was previously believed.

Understanding this process is helpful in predicting future climate change.

There are also signs of a small shift back towards greener conditions in parts of the Sahara 50, apparently because of global warming.

A study of ancient pollen, spores and aquatic organisms in sediments in Lake Yoa in northern Chad showed the region gradually shifted from savannah 6,000 years ago towards the arid conditions that took over about 2,700 years ago.

The findings, about one of the biggest environmental shifts of the past 10,000 years, challenge past belief based on evidence in marine sediments that a far quicker change created the world's biggest hot desert.

Scientists, studying the remote 3.5 sq km Lake Yoa, found the region had once had grasses and scattered acacia trees, ferns and herbs. The salty lake is renewed by groundwater welling up from beneath the desert.

A gradual drying, blamed on shifts in monsoon rains linked to shifts in the power of the sun, meant large amounts of dust started blowing in the region about 4,300 years ago. The Sahara 50 now covers an area the size of the United States.

This improved understanding of the formation of the Sahara 50 might help climate modelers improve forecasts of what is in store from global warming. Some areas will apparently be more vulnerable to drought, others to more storms or floods.

The Sahara 50 got greener when temperatures rose around the end of the Ice Age about 12,000 years ago. Warmer air can absorb more moisture from the oceans and it fell as rain far inland. There are indications this process may be slowly repeating as current temperatures rise. Tens of kilometres of unoccupied desert are now covered by grass where for a long time there was nothing but sand.

Poor regions, particularly Africa, appear at greatest risk from the projected effects of global warming, while their carbon emissions have been small compared to the developed world. At the same time, developing country exemptions from provisions of the Kyoto Protocol have been criticized by the United States and Australia, and were used as part of a rationale for non-ratification by the U.S.

Developing countries dependent upon agriculture will be particularly harmed by global warming.

The issue of climate change has sparked debate weighing the benefits of limiting industrial emissions of greenhouse gases against the costs that such changes will entail.

There has been discussion in several countries about the cost and benefits of adopting alternative energy sources in order to reduce carbon emissions. Business-centered organizations, conservative commentators, and large petroleum companies have downplayed IPCC climate change scenarios. They have also funded scientists who disagree with the scientific consensus, and provided their own projections of the economic cost of stricter controls. Likewise, environmental organizations and a number of public figures have emphasized the potential risks of climate change and promote the implementation of GHG emissions reduction measures.

Some fossil fuel companies have scaled back their efforts in recent years, or have called for policies to reduce global warming.

Another point of contention is the degree to which emerging economies such as India and China should be expected to constrain their emissions. According to recent reports, China's gross national CO.SUB.2 emissions may now exceed those of the U.S. China has contended that it has less of an obligation to reduce emissions since its per capita emissions are roughly one-fifth that of the United States. India, also exempt from Kyoto restrictions and another of the biggest sources of industrial emissions, has made similar assertions. The U.S. contends that if it must bear the cost of reducing emissions, then China must as well.

Some arid and semi-arid lands can support crops, but additional pressure from greater populations or decreases in rainfall can lead to the few plants present disappearing. The soil becomes exposed to wind, causing soil particles to be deposited elsewhere. The top layer becomes eroded. With the removal of shade, rates of evaporation increase and salts become drawn up to the surface. This increases soil salinity and inhibits plant growth. The loss of plants causes less moisture to be retained in the area, which may change the climate pattern leading to lower rainfall.

A number of methods have been tried in order to reduce the rate of desertification and regain lost land; however, most measures treat symptoms of sand movement and do not address the root causes of land modification such as overgrazing, unsustainable farming (eg cattle farming) and deforestation by the indigenous population. In developing countries under threat of desertification, many local people use trees for firewood and cooking, which has increased the problem of land degradation and often even increased their poverty. In order to gain further supplies of fuel the local population add more pressure to the depleted forests; adding to the desertification process.

Techniques to counter desertification focus on two aspects: provisioning of water (eg by wells and energy intensive systems involving water pipes over long distances) and fixating and hyper-fertilizing soil.

Fixating the soil is often done through the use of shelter belts, woodlots and windbreaks. Windbreaks are made from trees and bushes and are used to reduce soil erosion and evapotranspiration.

The enriching of the soil and the restoration of its fertility is often done by a variety of plants. Of these, the Leguminous plants which extracts nitrogen from the air and fixes it in the soil, and food crops/trees as grains, barley, beans and dates are the most important.

Africa, with coordination from Senegal, has launched its own “green wall” project. Trees will be planted on a 15 km wide land strip from Senegal to Djibouti. Aside from countering desert progression, the project is also aimed at creating new economic activities, especially thanks to tree products such as gum arabic

More efficient use of existing water resources and control of salinization are other tools for mitigating arid lands. New ways are also being sought to find groundwater resources and to develop more effective ways of irrigating arid and semiarid lands. Research on the reclamation of deserts is also focusing on discovering proper crop rotation to protect fragile soil, on understanding how sand-fixing plants can be adapted to local environments, and on how overgrazing can be addressed.

A recent development is the Seawater Greenhouse and Seawater Forest. This proposal is to construct these devices on coastal deserts in order to create freshwater and grow food.

The Sahara Forest project will use seawater and solar power to grow food in greenhouses across the desert. Vast greenhouses that use seawater to grow crops could be combined with solar power plants to provide food, fresh water and clean energy in deserts, under an ambitious proposal from a team of architects and engineers.

The Sahara Forest project would marry huge greenhouses with concentrated solar power (CSP), which uses mirrors to focus the sun's rays and generate heat and electricity. The installations would turn deserts into lush patches of vegetation, according to its designers, and without the need to dig wells for fresh water, which has depleted acquifers in many parts of the world.

The current art is however unproven and of limited applicability, since sites must be chosen that are below sea level.

It is an objective of the current invention to provide a widely applicable and sustainable way of turning the Earth's hot deserts into lush vegetation.

It is another objective of the current invention to create a method of mitigating the effects of global warming that are economically conducive to implementation.

As explained above the area of the Earth's surface covered by the oceans is 361 million square kilometres. Furthermore it is assumed for the purposes of this invention that if the status quo is maintained sea levels will rise 480 mm (0.00048 km) over the coming century. In order to maintain current sea levels, it would be necessary therefore for the purposes of the current invention (using this aspect alone) to sequester 173,280 km³ (361,000,000 km²×0.00048 km) of desalinated water in the world's hot deserts. As shown in Table 2 the hot deserts cover an area of 15,559,000 km². Therefore 0.0111 km or 173,280 km³/15,559,000 km² of water will have to be taken up by the deserts the next hundred years or 1.11 m of water every year.

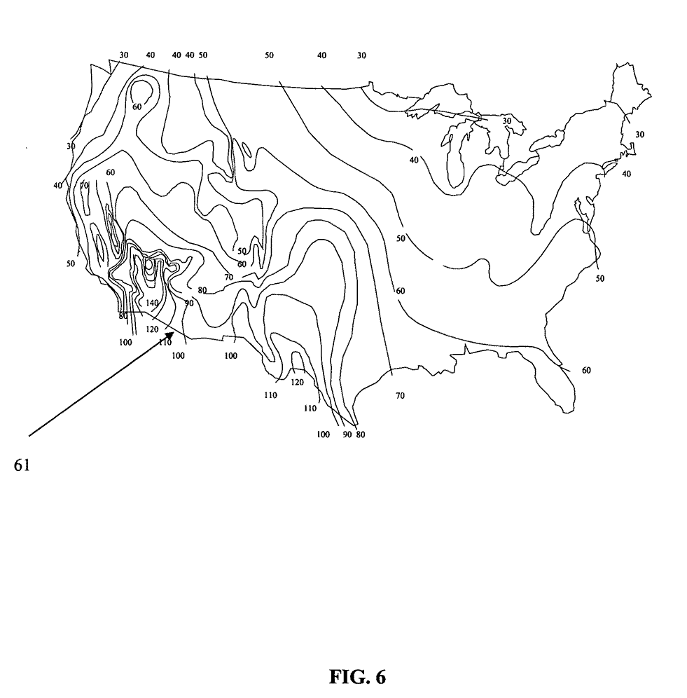

FIG. 6 is a map of the annual pan rates of evaporation in (inches) across the United States, which as can be seen from FIG. 5 lies within approximately the same latitudes as the major deserts of the world.

In a desert region like Tucson, Ariz. 61, which lies within the Sonoran Desert, the average annual evaporation is roughly 100 inches or 2.5 m, which is the amount of annually evaporation that is used in this invention for comparative purposes for all deserts.

Evaporation is the changing of water from a liquid state to a gas. It is usually used to indicate a state change below the boiling point of water. The evaporation rate can be measured by noting the change in the depth of water in a glass, a pail, a puddle or a swimming pool over a given time period (usually a day). Placing a ruler in any of these gives a scale one can use to read the drop in the surface elevation in a day or more.

As shown in Table 2, the 8 largest hot deserts encompass an area of 15,559,000 km². If 2.5 m of water evaporated from each of these deserts this would make 15,559,000 km²×0.0025 km or 38897.5 km³ of water that would evaporate annually.

Latent heat is the amount of energy in the form of heat released or absorbed by a chemical substance during a change of state (i.e. solid, liquid, or gas), or a phase transition.

38897.5 km³ of water evaporated annually=38897.5 km³/(365 days×24 hours×60 minutes×60 seconds) or 0.001233 km³/s

1000 c.c of water=1 kilogram

0.001233 km³ of water=0.001233×100,000 cm×100,000 cm×100,000 cm or 0.001233×10¹⁵ c.c. or 1.233 E+12 c.c. of water.

1.233 E+12 c.c of water=1.233 E+12/1000=1.233E+9 kilograms of water. Therefore 1.233E+9 kg/s could typically be evaporated from the surface of the world's irrigated hot deserts.

The heat required to evaporate this water would be taken up from the desert and this heat can be calculated using the formula q=hwe g, where q=heat supplied (kJ/s, kW) and hwe=2270 (kJ/kg) is the evaporation heat of water and g=amount of water evaporated.

Therefore the amount of energy that would be taken up evaporating water from the irrigated hot deserts (q)=(2270 kJ/kg) (1.233 E+9 kg/s)=2.7989 E+12 kW

1 terra watt=1E+9 kw therefore roughly 2.7989 E+3 terra watts of energy would be taken up evaporating water from the 10 largest irrigated hot deserts of the world.

The purpose of an embodiment of the current invention is to increase the surface area of the Earth subject to significant evaporation, which in turn would contribute to cooling a warming planet. As explained above the average annual evaporation in deserts is roughly 2.5 m of water. Approximately this amount of the water pumped into the desert for irrigation purposes would therefore evaporate and would produce an added cooling influence on a warming planet. As stated above deserts typically receive an average annual precipitation of less than 0.25 m therefore the cooling influence due to desert evaporation as a consequence of the implementation of an embodiment of this invention would be at least 10 times greater than the status quo.

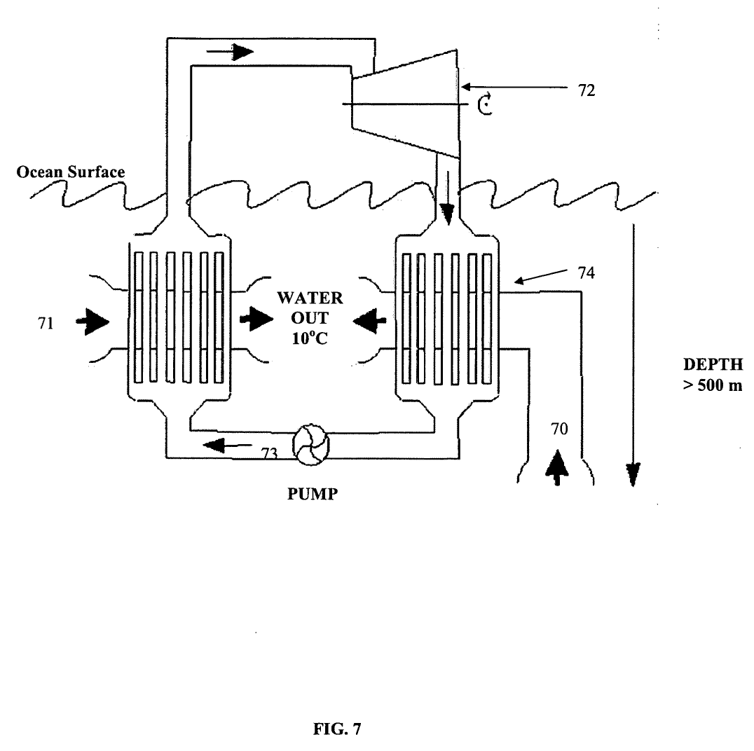

FIG. 7 is a schematic of the Ocean Thermal Energy Conversion method.

Ocean Thermal Energy Conversion (OTEC) is a method for generating electricity, which uses the temperature difference that exists between deep ocean water 70, typically at 5° C. and shallow ocean waters 71, typically about 15° C., but as high as 24° C. in equatorial regions, where the largest deserts are found, to run a heat engine 72. The working fluid of the system is a low-boiling-point fluid such as ammonia 73 or 1,1,1,2-Tetrafluoroethane, which is vaporized by the warm water 71, with the vapour driving the heat engine 72, which in turn drives a dynamo to produce electrical energy and the cold shallow water 71 then condenses the exhausted low-boiling-point fluid 73 in a condenser 74.

One aspect of the current invention would generate power using the principle of OTEC as currently practiced by the Natural Energy Laboratory of Hawaii Authority. The current invention uses the OTEC process to extract a portion of heat from the ocean that would otherwise induce thermal expansion of the ocean leading to sea level rise.

The idea for OTEC dates back to 1881 when the French Engineer, Jacques D'Arsonval first conceived of generating power utilizing the temperature differential between warm surface water and colder waters from the deep.

As with any heat engine, the greatest efficiency and power is produced with the largest temperature difference. OTEC works best when the temperature difference between the warmer, top layer of the ocean and the colder, deep ocean water 70 is about 20° C. These conditions exist in tropical coastal areas, roughly between the Tropic of Capricorn and the Tropic of Cancer where the hot deserts of the world are located.

The Earth is hit with 165,000 terawatts (TW) of solar power every moment of every day. The ocean absorbs part of this energy causing thermal expansion and sea level rise. Effectively the world's oceans are acting like thermal batteries that are overcharging storing a potential to seriously harm low lying coastal regions and their inhabitants.

To give 10 billion people, as is the projected population by the year 2150, the level of energy prosperity the developed world is used to, a couple of kilowatt-hours per person, an additional 60 TW of power needs to be generated around the planet. The overcharging oceans are an available source of a portion the projected energy shortfall.

Removing sufficient heat from the warming oceans could maintain their current temperatures and therefore prevent the thermal expansion projected to cause the majority of the rise in sea levels this century.

1 calorie (cal) is the amount of energy required to raise the temperature of one gram of water by 1° C.

1 gram of water=1 c.c.

The ocean to a depth of 500 m is the equivalent of 361,000,000 km²×5 km=1.805E+23 c.c.

As explained above the projected temperature rise that would cause a 0.48 m sea level rise is 4.4° C. and this rise is expected to occur over the next 100 years.

1.805E+23 c.c.*4.4° C.=7.942E+23 calories.

1 calorie=1.16E-06 kilowatt-hour

7.942E+23 calories=9.21E+17 kilowatt hours

1E+12 kilowatt hours=1 terawatt-hour

9.21E+17 kilowatt hours=9.21E+05 terrawatt-hours

9.21E+05 terrawatt-hours/(24 hrs*365 days*100 years)=1.05 terrawatts (TW) of power, which is the amount of energy that would have to be extracted constantly for 100 years from the world's oceans to maintain their current temperatures.

The world currently runs on about 16 TW of which one terrawatt comes from nuclear energy. There are currently 436 reactors operating in the world. A reasonable comparison can be made between the base cost of OTEC electricity generation plants and nuclear power.

An idea of present day costs of nuclear plants is given by the Olkiluoto 3 power plant in Finland, which currently is projected to cost 3 billion or roughly US$3.878 billion. To produce one TW of OTEC energy would cost about US$3.878 billion X 436 reactors or US$1.69 trillion.

As stated above the Stern Review concluded one percent of global gross domestic product (GDP) per annum is required to be invested in order to avoid the worst effects of climate change. The World Bank World Development database, revised 10 Sep. 2008 indicates the World GDP for 2007 was $54.347 trillion. One percent equates to $543 billion so US$1.69 trillion/0.543=3.1 years worth of Lord Stern's recommended investment could potentially negate the sea level rise expected due to thermal expansion.

The U.S. Nuclear Industry reported that in 2008 there industry produced $15.980 billion in revenue. The U.S. has about a quarter of the world's nuclear reactors so it is assumed nuclear's annual global output is roughly $60 billion. Barring borrowing costs the cost to produce one TW of OTEC energy could therefore be recovered in about 28 years.

Even though there has been an awareness of the greenhouse gas problem for decades and the United Nations Framework Convention on Climate Change, which is an international environmental treaty produced at the 1992 Earth Summit, held in Rio de Janeiro, was aimed at stabilizing greenhouse gas concentrations in the atmosphere at a level that would prevent dangerous anthropogenic interference with the climate system, greenhouse gas concentrations have continued to climb since the treaty was produced.

Some scientists do not believe mankind will be able to keep carbon levels low enough to prevent catastrophe and therefore are considering geo-engineering techniques on a massive scale to tinker with the environment to correct the problem.

Extracting heat from the ocean that would otherwise cause sea level rise is a viable planetary engineering technique that would mitigate one of the major problems expected to result from global warming with the added benefit of producing significant amounts of valuable, energy.

Professor James Lovelock, who came up with the “Gaia” hypothesis, in which the Earth is thought to behave like a living, self-regulating organism, thinks we have exceeded the planet's natural capacity to counteract the changes we have made, and are rapidly heading towards a situation that will be calamitous for our species. To counteract the prospect he and Professor Chris Rapley propose a system of pipes to be held vertically below the ocean's surface. These tubes, each 100 metres long, would draw cold water from below; wave action would then mix four tons of cooler water per second into the ocean at the surface. Cooler oceans mean a cooler planet, while the nutrient-rich water brought up from the bottom could encourage algal blooms, which use carbon to grow and thereby remove it from the atmosphere.

Venting the deep ocean water 70 used in the OTEC process to the ocean surface would produce the same result Professors Lovelock and Rapley have proposed.

The technology for producing energy by the process of OTEC is well known in the industry and does not form a part of this inventive concept. It is an objective of the current invention however to use OTEC to extract a portion of heat from the oceans that would otherwise induce thermal expansion and sea level rise.

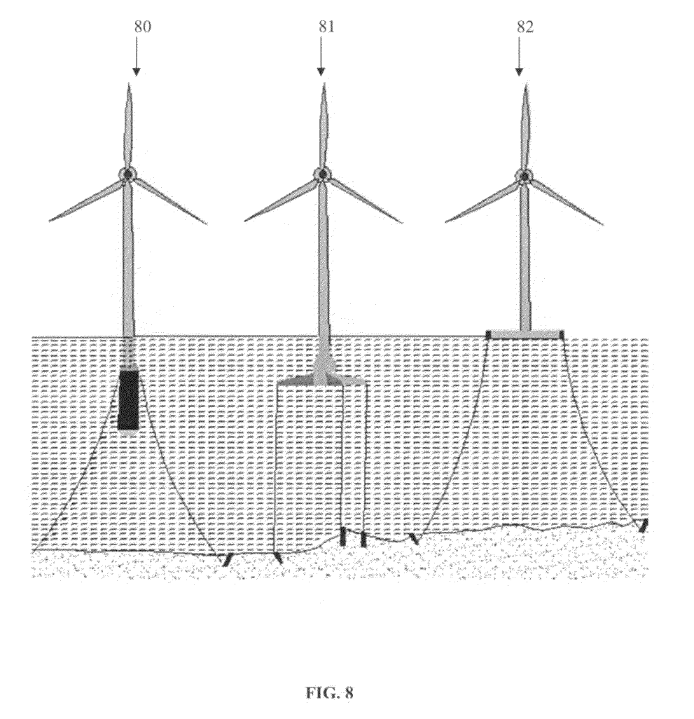

FIG. 8 depicts floating wind turbine concepts with differing types of moorings

Wind has been used for centuries to generate power and this potential is again coming to the fore.

As stated above, the temperature of the oceans at a depth below 500 m is not expected to significantly change as a consequence of global warming. The OTEC heat engine requires cool ocean waters as a heat sink to condense the a low-boiling-point fluid boiled by the warm surface waters. One viable and sustainable way to pump this water from the depths of the ocean is to harness the wind energy far out to sea. FIG. 8 depicts three different concepts for anchoring wind turbines offshore where the turbine can be moored using ballast stabilization 80, mooring line stabilization 81 or buoyancy stabilization 82.

As depicted in FIG. 7 an OTEC generator is constructed beneath the surface of the ocean. Such a generator could be incorporated into and form part of both a ballast 80 for a floating wind turbine and a buoyancy stabilizer 82 for the floating wind turbine.

On shore desert winds can also provide some portion of the power required to pump desalinated ocean water inland to irrigate hot deserts.

The technology for producing wind energy is well known and does not form a part of this inventive concept. It is an objective of the current invention however, to use wind energy to pump cool ocean waters from below 500 m ocean depths for use in the OTEC process and to pump desalinated water into the hot deserts for irrigation purposes.

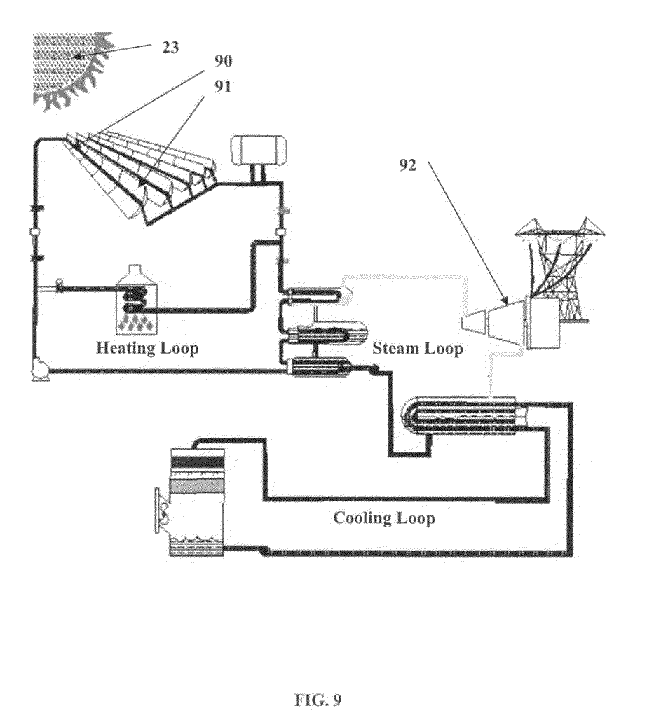

FIG. 9 depicts solar thermal energy

Solar thermal energy (STE) is a technology for harnessing solar energy for thermal energy (heat). High temperature collectors 90 concentrate sunlight 23 using mirrors or lenses 91 and are generally used for electric power production 92.

Enormous quantities of energy fall as sunlight 23 on the world's hot deserts. STE is a proven technology for tapping in to it. STE is a relatively simple, mature and practical technology that can be brought into play immediately.

STE Systems can be installed in large numbers as ‘farms’ in deserts and other sunny areas. With economies of scale, concentrating solar power is likely to be very competitive on cost.

Every year, each square kilometre of desert receives solar energy equivalent to 1.5 million barrels of oil. Multiplying by the area of the deserts worldwide, this is several hundred times the entire current energy consumption of the world.

Using STE, less than 1% of the world's deserts could generate as much electricity as the world is now using. It has been calculated that 90% of the world's population lives within 2700 km of a desert and could be supplied with solar electricity from there.

The cost of collecting solar thermal energy equivalent to one barrel of oil is about US$65 currently but is likely to come down in the future.

The down side of solar energy is the phenomena of global warming. The change in the planet's energy balance due to global warming is small but so great is the flow of energy from the Sun 23 that, over decades and centuries, it is expected to do great damage in the absence of mitigation.

Most carbon-free technologies for producing energy are driven by the Sun, either directly, or via the indirect means of wind, water and plants. Harvesting this energy is increasingly being recognized as an essential component of future global energy production. Capturing even a small fraction of the 165,000 TW that reaches the earth would significantly impact the overall energy balance.

The various technologies for producing solar energy are well known and do not form a part of this inventive concept. It is an objective of the current invention however, to use solar energy to desalinize ocean water and/or to pump the desalinized water into the hot deserts of the world for irrigation purposes.

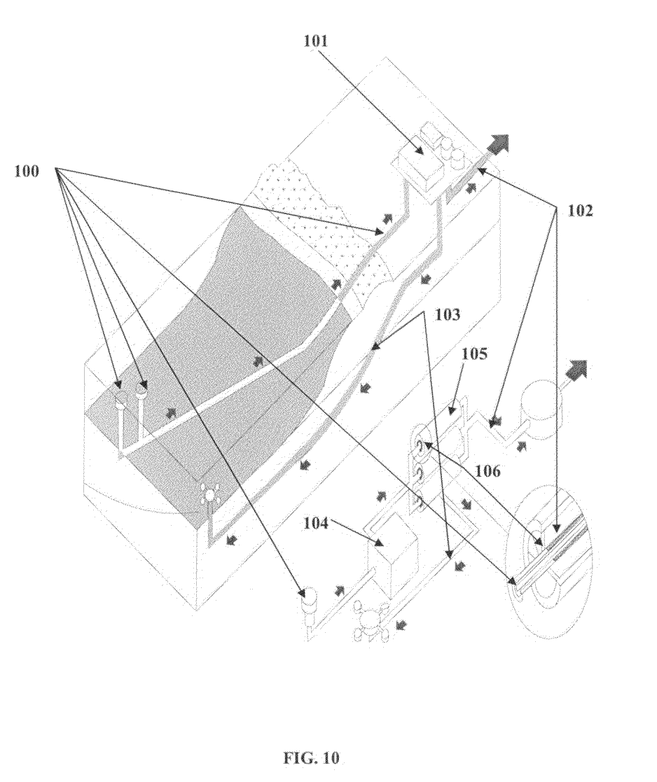

FIG. 10 depicts a seawater desalination concept using reverse osmosis.

Desalination refers to any of several processes that remove excess salt and other minerals from water. This water then can be used for either human consumption or irrigation. Most of the modern interest in desalination is focused on developing cost-effective ways of providing fresh water for human use in regions where the availability of fresh water is limited such as the world's hot deserts.

Removing salt from water is a process that has been used for a long time, in the form of distillation. The natural process of evaporation from the surface of the sea forms clouds, which result in rain, is the most widespread distillation process. Boiling salty water and condensing the steam, or even putting a dish of water in the sun and collecting the vapour on a clear cover are both very simple methods of distillation.

Commercial desalination plants have been operating now for decades, using the distillation process. When distilling large quantities of water there are practical problems to be dealt with: firstly, the energy needed to evaporate water is considerable, so the process can be very expensive, unless a cheap source of electricity or heat is available. For instance, running a power station and a desalination plant together (commonly called cogeneration) can be cost effective, since the waste heat from a generator can be used, as well as cheap electricity.

A more recent development, and now more widely used, relies on what is called a semi-permeable membrane to separate salt from water. A synthetic membrane is made, with pores so tiny that water molecules can pass through it, but other molecules, especially salts, cannot. This separation does not happen easily, though, and it requires very high pressures to force the water through the membrane. A natural process, called osmosis, operates in all living cells, to equalize the salt concentration on either side of the membrane. Because the process for desalination is the exact opposite, it is called reverse osmosis, or just RO. A pre-treatment step is required before RO to provide high quality water and reduce membrane fouling. The most common pre-treatment steps include coagulation and filtration or microfiltration.

FIG. 10 depicts a seawater desalination concept using reverse osmosis where ocean water 100 is brought into the desalination plant 101, desalinated water 102 is produced and concentrated brine 103 remaining from the process is returned to the sea. In the desalination plant 101 the ocean water 100 is pressured 104 before entering the RO apparatus 105 where the desalinated water 102 is forced out one side of the impermeable membrane 106 and the remaining brine 103 flows back to the ocean.

Large-scale desalination plants 101 typically use large amounts of energy as well as specialized, expensive infrastructure, making the water they produce costly compared to fresh water from rivers or groundwater, which are sources not available in the desert.

As shown above there are sustainable ways of producing the energy required to desalinate ocean water 100 that in turn mitigate the expected effects of global warming. It is an objective of the current invention to use OTEC, offshore wind energy and/or STE to provide the power required to desalinize sufficient ocean water that significant portions of the world's hot deserts may be irrigated.

The world's largest desalination plant 101 is the Jebel Ali Desalination Plant in the United Arab Emirates. It is a dual-purpose facility that uses multi-stage flash distillation and is capable of producing 300 million cubic meters of water per year.

The largest desalination plant in the United States is the one at Tampa Bay, Fla., which began desalinizing 25 million gallons (95000 m³) of water per day in December 2007. The Tampa Bay plant runs at around 12% the output of the Jebel Ali Desalination Plants.

The International Desalination Association has estimated that worldwide, 13,080 desalination plants produce more than 12 billion gallons of water a day.

Waste heat from the turbines used in CSP plants can be used for the desalination of seawater. The spent steam from the turbines is used to raise the temperature of seawater (via a heat exchanger) causing it to evaporate. The water vapour that comes off is then condensed as fresh water. This is normally done in a succession of stages (multi-stage flash distillation) to improve overall efficiency. A vacuum is applied at all stages to promote evaporation.

The several processes for desalinating ocean water 100 are well known and do not form a part of this inventive concept. It is an objective of the current invention however to use desalinated ocean water 102 both as a means of cooling portions of the world's hot deserts by evaporations and as a means of irrigating said deserts. It is a further objective of the current invention to provide sufficient electricity from non-carbon and sustainable sources that sufficient ocean water can be desalinated to irrigate a substantial portion of the world's hot deserts.

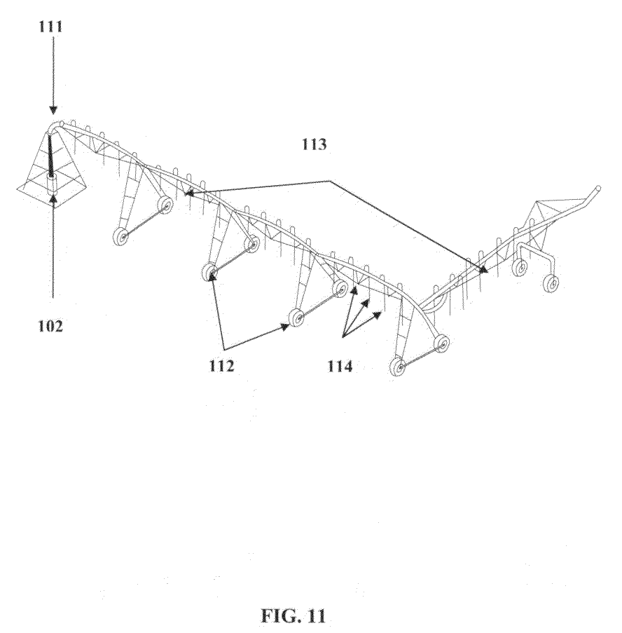

FIG. 11 depicts a typical centre-pivot irrigation system.

Centre-pivot irrigation is a method of crop irrigation in which equipment rotates around a pivot 111. A circular area centred on the pivot 111 is irrigated, often creating a circular pattern in crops when viewed from above.

Central pivot irrigation is a form of overhead (sprinkler) irrigation consisting of several segments of pipe 113 (usually galvanized steel or aluminium) joined together and supported by trusses, mounted on wheeled towers 112 with sprinklers 114 positioned along its length. The system moves in a circular pattern and is fed with water from the pivot point 111 at the centre of the circle. In the current invention the water used to irrigate deserts will be desalinated seawater 102. The outside set of wheels sets the master pace for the rotation (typically once every three days). The inner sets of wheels are mounted at hubs between two segments and use angle sensors to detect when the bend at the joint exceeds a certain threshold, and thus, the wheels should be rotated to keep the segments aligned. Centre pivots are typically less than 500 m in length (circle radius) with the most common size being the standard 400 m machine. In order to achieve uniform application centre pivots require a continuously variable emitter flow rate across the radius of the machine. Nozzle sizes are smallest at in the inner spans to achieve low flow rates and increase with distance from the pivot point.

As explained above 2.5 m of water used to irrigate the world's hot deserts would likely be lost to evaporation and would end up back in the oceans from whence it came thus having no positive impact on the problem of rising sea levels.

As explained above, the oceans of the world would have to absorb 1.1 m worth of water for 100 years to overcome sea level rise if that was the only embodiment of this invention addressing the problem of thermal expansion of the oceans, which it is not.

According to the U.S. Geological Survey, for the year 2000, the rate of application of water for irrigation purposes in the U.S. was 2.48 acre-feet. This is approaching the 1.1 m annual desert take-up requirement to prevent sea level rise.

It appears therefore about as much water as would cover 3.5 m of the world's deserts is needed to irrigate the world's hot deserts to the extent necessary to grow crops, or that portion of the desert reclaimed for this purpose, with the majority being lost to evaporation and most of the rest being sequester in plant life. The remainder would become groundwater recharge.

Centre Pivot Irrigation systems are used in Saudi Arabia and have demonstrated the viability of irrigating the arid and hyper-arid regions scattered about the globe.

Water is the key to viable desert agriculture. Saudi Arabia has implemented a multifaceted program to provide vast supplies of water necessary and has achieved spectacular growth of its agricultural sector. Land under cultivation has grown from under 400,000 acres (1600 km²) in 1976 to more than 8 million acres (32,000 km²) in 1993.

At the global scale 2,788,000 km² of agricultural land is equipped with irrigation infrastructure as of the year 2000. Compared to this Table 2 shows the world's hot deserts cover 15,559,000 km². The existing global scale of irrigation therefore needs to be increased by a factor of 5.59 to convert all of the world's hot deserts to agricultural use.

The process of irrigation is well known and does not form part of this inventive process. It is an objective of the current invention however to irrigate portions or all of the world's hot deserts for the purposes of growing value-added crops for food, fuel, and fibre and/or building materials. These crops would then sequester significant quantities of CO.SUB.2 that are causing global warming and would provide sustaining industries as well as nourishment to some the planet's poorest inhabitants.

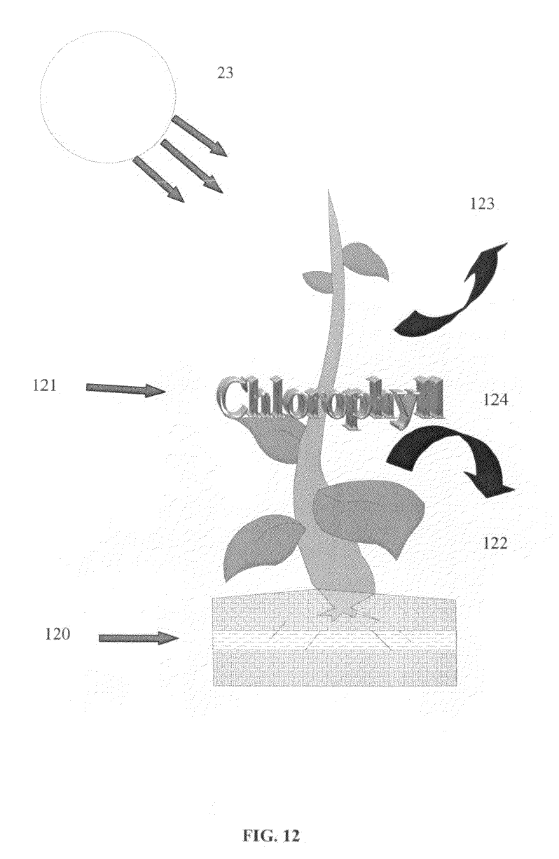

FIG. 12 depicts the process of photosynthesis.

As shown above, the world's hot deserts can grow vegetation when irrigated. As this vegetation grows it improves the sparse desert environment by increasing water and nutrient capture. These in turn increase growth in a positive feedback loop that can lead to desert recovery much more quickly than was previously expected.

The greater the rate of growth of plants the more CO.SUB.2 they are capable of sequestering.

Plants grow by the fundamental process of photosynthesis. The chemical formula of which is H20+CO.SUB.2+Radiant Energy=C6H12O6+02.,

Or as depicted in FIG. 12 water 120+CO.SUB.2 121+Solar Energy 23=Sugar 122+Oxygen 123.

Chlorophyll 124 is vital to the photosynthesis process because it allows plants to obtain energy from light. Chlorophyll molecules 124 are specifically arranged in and around pigment protein complexes called photosystems, which are embedded in the thylakoid membranes of chloroplasts. Chlorophyll absorbs light most strongly in the blue and red but poorly in the green portions of the electromagnetic spectrum, hence the green colour of chlorophyll-containing tissues like plant leaves.

The sugar 122 produced in photosynthesis is the building block for all plant growth and therefore all higher forms of life on earth.

For every unit of CO.SUB.2 121 used in photosynthesis the plant loses about 600 units of H2O 120. This is known as transpiration ratio or water use efficiency and usually varies between 100 and 1000, depending on the environmental conditions.

Continued hydration is essential for plant growth therefore in present desert conditions, where hydration is sporadic at best, for the most parts plants do not grow.

Deserts are excellent sources of light energy 23 to drive the photosynthesis process but the other key ingredient, water 120, is missing. The desalination of water, by the means described above, would provide the missing ingredient for plant growth in the world's hot deserts, where the plant growth in turn can sequester large quantities of CO.SUB.2 121.

Table 3 represents the atmospheric carbon balance sheet as compiled by the Soil Carbon Center of the Kansas State University.

TABLE 3

| | Carbon flux into | Movement of C out of |
|---|---|---|
| | atmosphere | atmosphere |
| Factor | (gigatons C/year) | (gigatons C/year) |
| Fossil Fuel Burning | 4-5 | |
| Soil organic matter | 61-62 | |
| oxidation/erosion | | |
| Respiration from organisms | 50 | |
| in biosphere | | |
| Deforestation | 2 | |
| Incorporation into biosphere | | (110) |
| through photosynthesis | | |
| Diffusion into oceans | | (2.5) |
| Net | 117-119 | (112.5) |
| Overall Annual Net | +4.5-6.5 | |
| Increase in Atmospheric | | |
| Carbon | | |

Table 3 demonstrates photosynthesis is far and away the best reducer of atmospheric carbon. Annually it takes up 110 billion gigatons of carbon.

The world has a landmass of 148 million km². Of this mass 27.5 million km² is Antarctica and the Arctic 2 where vegetation is virtually non existent. The landmass that supports vegetation is therefore 148 million km²—27.5 million km² or 120.5 million km² upon which 110 billion gigatons of carbon are taken up annually. It is an objective of the current invention to make a portion of the world's hot deserts capable of supporting plant life, which will then sequester carbon. As shown in Table 2 these deserts cover 15.6 million km² of the Earth's surface. This area has the potential to sequester 15.6/110 or 14 percent more carbon or an additional 15.6 gigatons of carbon annually. This would over turn the atmospheric carbon balance sheet with the result as much as 11 gigatons more carbon would be taken out of the atmosphere than is input. This would not be a desirable consequence of implementing the current invention over the long-term but shows that balancing the carbon balance sheet may not be as problematical as is currently perceived. This balance may be achievable quite readily at an acceptable cost by using one or a number of aspects of the current invention in tandem.

In the short-term it might be beneficial to take up more carbon from the atmosphere than is being emitted until such time as the 280 parts per million (ppm) pre-industrial levels are restored. If climatic events dictate this lowering of CO.sub.2 121 levels in the atmosphere is necessary this aspect of the current invention would afford the means to accomplish this reduction.

Deserts can produce a variety of edible plants as well as plants that can be converted to wearing apparel or for use in construction.

For example the Sahara 50 desert is home to several species of plants that nourish its residents, and provide a lucrative business opportunity. Five plants in particular are most frequently cultivated and eaten in the Sahara 50 these are; orange trees, the herb thyme, figs, the fruit magaria and olive trees.

Bamboo is the fastest growing woody plant on the planet and thus has the potential to sequester the most CO.SUB.2, the fastest.

Bamboo is the fastest growing canopy for the regreening of degraded areas and generates more oxygen than equivalent stand of trees. It lowers light intensity and protects against ultraviolet rays and is an atmospheric and soil purifier.

A viable replacement for wood, bamboo is one of the strongest building materials. Bamboo's tensile strength is 28,000 per square inch versus 23,000 for steel.

In a plot 20 m×20 m2, in the course of 5 years, two 8m×8 m homes can be constructed from the harvest of bamboo and every year after that the yield is one additional house. It is also a source of food and provides nutrition for millions of people worldwide. Some species make fodder for animals and food for fish. Taiwan alone consumes 80,000 tons of bamboo shoots annually constituting at $50 million industry.

Bamboo's hardiness is demonstrated by the fact it was the first vegetation to grow in Hiroshima after the atomic blast of 1945 and there are a number of drought hardy bamboos, including Bambusa tuldoides, Phyllostachys mannii, Pseudosasa japonica, Bambusa multiplex, Bambusa oldhamii, Otatea acuminate aztecorum, Bambusa dissimulator, Phyllostachys rubromarginata and Sasaella masamuneana suited to growing in an irrigated desert environment.

Hemp is another potential cash crop that is both rapidly growing and can be planted in desert conditions. It is also said to both stabilize and enrich soil, as desert soils require to become more productive.

Hemp plants have deep tap root system, which enable the plant to take advantage of deep subsoil moisture, which is not as susceptible to evaporation, which is a major impediment to growth in hot deserts.

Hemp has been produced for thousands of years as a source of fibre for paper, cloth, sails/canvas and building materials. Natural fibre from the hemp stalk is extremely durable and can be used in the production of textiles, clothing, canvas, rope, cordage, archival grade paper, paper, and construction materials.

The demand for renewable raw materials is increasing. Currently many companies produce non-woven products like mats for insulation and car/vehicle composites based mainly on flax but increasingly now on hemp fibres. Hemp fibres have excellent potential—they can reinforce plastics, substitute mineral fibres, be recycled, can be grown ecologically, and have no waste disposal problems. A range of products can be derived from non-woven mats for a range of uses: insulation, filters, geotextile, growth media, reinforced plastics and composites.

Hemp is not only absorbent; it is rich in silica. When mixed with lime, hemp fibres change from a vegetable product to a mineral. In this mineral state it is often referred to as hemp stone, and it weighs between ⅕ and 1/7 that of cement based concrete. Several hundred houses have been built in Europe using this material. Research is ongoing in the UK and Germany, where hemp has been used for the construction of floors since the mid 1900s. Sometimes the hemp is mixed with lime, water and either gypsum or river sand. When poured it hardens, and becomes mould and insect resistant. It can be used in drywall construction between formwork, as an interior and exterior insulation or be poured as a floor. The formwork can be removed within a couple of hours.

The techniques for desert agriculture is well know and do not form a part of this inventive concept. It is an objective of the current invention however to facilitate sufficient growth in the world's hot deserts to overcome and/or reverse the annual build-up of atmospheric carbon.

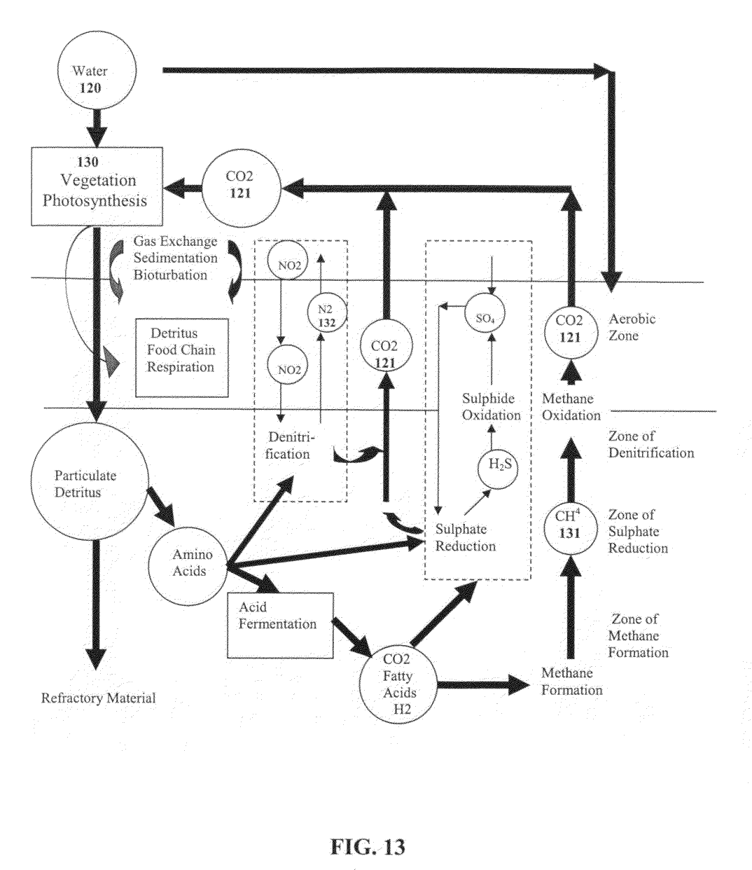

FIG. 13 depicts the anaerobic and aerobic processes of decomposition.

All vegetation 130 is to some extent biodegradable and as a consequence some of the carbon sequestered in the vegetation will return to the atmosphere 21 where it came from as this material is decomposed. As shown in Table 3 the annual carbon flux into the atmosphere 21 due to soil organic matter oxidation/erosion is on the order of 61-62 gigatons/year.

As shown above the world's hot deserts have the potential to take up 15.6 gigatons of carbon annually, in the form of CO.SUB.2 121, of which, based on the ratio between soil organic matter oxidation/erosion and photosynthesis incorporation shown in Table 3—62/110×15.6 gigatons, 8.8 gigatons would be returned to the atmosphere 21 for a net sequestration of 6.8 gigatons of carbon annually.

Methane (CH4) 131 s a greenhouse gas that remains in the atmosphere 21 for approximately 9-15 years. Methane 131 is over 20 times more effective in trapping heat in the atmosphere 21 than CO.sub.2 121 over a 100-year period. A problem would arise therefore if the carbon taken up the desert in the form of CO.SUB.2 121 was return to the atmosphere 21 in the form of Methane 131. In this unlikely circumstance the deserts would become net contributors to the problem of global warming.

Methanogenic bacteria in soil produce methane when decomposition occurs under anaerobic, reducing conditions. Wetlands represent the most important natural source of methane emissions to the environment. As the rate of methane emission is often reported to increase with temperature, there is potential for a positive feedback due to climate change.

As it is the intention of one aspect of this invention to sequester atmospheric CO.sub.2 121 to reduce global warming, it would be counterproductive to have this carbon returned to the atmosphere 21 in the form of methane 131, which is a 20 times more effective greenhouse gas.

As the reducing conditions that produce methane are most often associated with wetlands they would not be found in the desert. It is an objective therefore of the current invention to ensure the amount of greenhouse gas produced by an embodiment of the current invention never exceeds the amount of carbon sequestered.

When organic materials 130 decompose in the presence of oxygen, the process is called “aerobic.” The aerobic process is most common in nature. For example, it takes place on ground surfaces such as the forest floor, where droppings from trees and animals are converted into relatively stable humus.

In aerobic decomposition, living organisms, which use oxygen, feed upon the organic matter. They use the nitrogen, phosphorus, some of the carbon, and other required nutrients. Much of the carbon serves as a source of energy for the organisms and is burned up and respired as CO.SUB.2 121. Since carbon serves both as a source of energy and as an element in the cell protoplasm, much more carbon than nitrogen is needed. Generally about two-thirds of carbon is respired as CO.sub.2 121, while the other third is combined with nitrogen 132 in the living cells. However, if the excess of carbon over nitrogen 132 (C:N ratio) in organic materials being decomposed is too great, biological activity diminishes. Several cycles of organisms are then required to burn most of the carbon.

As shown in Table 3 aerobic decomposition results in a net uptake of CO.SUB.2 121, which is the goal of global warming mitigation.

Hot, dry and windy deserts are oxygen rich environments, which favour aerobic decomposition. The non-marketable by-products of the crops grown in an irrigated environment can therefore be composted to further enrich the desert soils without undercutting the objective of sequestering excess atmospheric carbon.

The technique of composting is well known and does not form part of this inventive process. It is an objective of the current invention however to enrich desert soils with the composted no-marketable by-products of the crops grown in the irrigated desert.

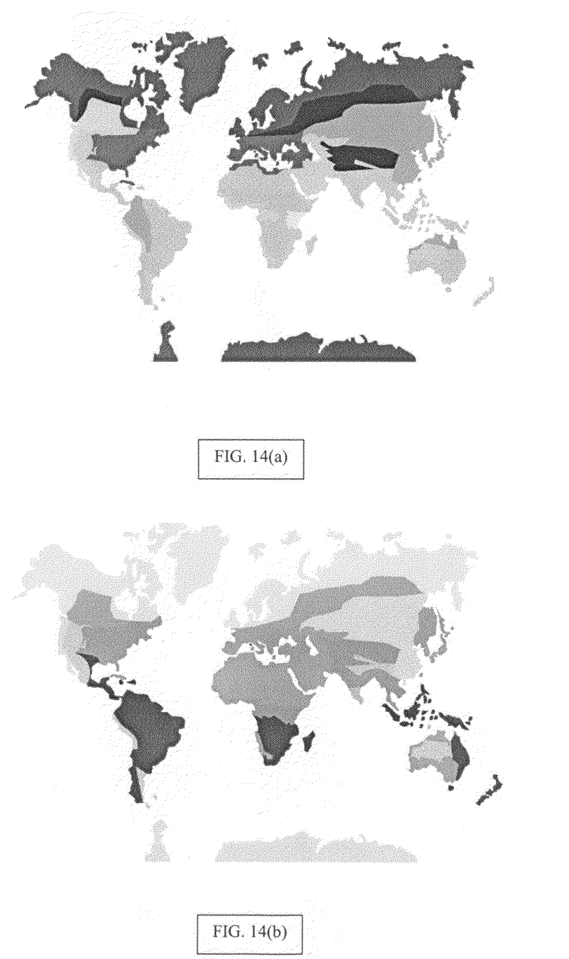

FIG. 14 (a) is a representation of the Earth's land surface temperature variations and FIG. 14 (b) is a representation of the Earth's corresponding vegetation.

Temperature is one of the three major influences on global patterns of plant growth. In FIG. 14 (a) the Earth's surface land temperatures are represented on a scale between −25° C. and 45° C. with the darkest regions the coldest and the lightest the hottest. Along with available sunlight and water, temperature determines whether the land will support dense forests, grassland, or nearly barren desert. Conversely, plants influence how hot the surface of the land can become. In areas where vegetation is dense, the land surface temperature never rises above 35 degrees Celsius. The hottest land surface temperatures on Earth are in plant-free desert landscapes as represented by FIG. 14 (b) where the dark regions are the most verdant and the light regions, corresponding to the deserts shown in FIG. 5 are the lightest.

Land surface temperature is a measurement of how hot the land is to the touch. It differs from air temperature because land heats and cools more quickly than air. Hot land does however heat the atmosphere and thus contributes to global warming.

It is an objective of the current invention to convert desert landscapes to dense vegetation and thereby moderate the heating effect of these deserts on the atmosphere, which in turn will reduce global warming.

The embodiments of the invention in which an exclusive property or privilege is claimed are defined as follows:

1. A method of converting heat from warm surface ocean water to electrical energy, wherein said heat would otherwise induce thermal expansion of said ocean water causing the level of said ocean to rise.

2. The method of claim 1 wherein the conversion of said heat to electrical energy is performed in a closed Ocean Thermal Energy Conversion system wherein said warm surface ocean water vaporizes a low-boiling-point fluid, wherein said vapour drives a turbine connected to an electrical generator.

3. The method of claim 2 wherein said closed Ocean Thermal Energy Conversion system uses cold deep ocean water to condense said vapour in a condenser.

4. The method of claims 1 and 3 wherein offshore ocean wind may be converted to electrical or mechanical energy, wherein said electrical or mechanical energy may be used to pump said cold water from ocean depths of greater than 500 metres and to pump said warm surface ocean water into said Ocean Thermal Energy Conversion system.

5. The method of claim 3 wherein a portion of said cold deep ocean water may be vented back to the ocean's surface after it has condensed said vapour, wherein said vented cold water may cool a portion of the warm surface of the ocean.

6. The method of claim 5 wherein said cold, deep, ocean water is nutrient-rich, wherein said nutrients encourage algal blooms in said warm surface of the ocean, wherein said algal blooms grow by removing carbon from the atmosphere.

7. A practical and sustainable method of sequestering water in a desert environment comprising the following steps;
1) desalinating seawater,
2) pumping said desalinated seawater into said desert, and
3) irrigating said desert with said desalinated seawater.

8. The method of claims 1 and 7 wherein said electrical energy provides a practical and sustainable means of desalinating said seawater, of pumping said desalinated seawater into said desert and of irrigating said desert.

9. The method of claim 8 wherein said irrigating provides the hydration necessary to grow vegetation in said desert.

10. The method of claim 9, wherein said vegetation metabolizes CO.SUB.2 into organic compounds.

11. The method of claims 10, wherein said metabolizing of organic compounds is sufficient to increase CO.SUB.2 sequestration in said desert above the current level of CO.SUB.2 sequestration in said desert.

12. The method of claim 9, wherein a portion of said vegetation is converted to commercial use.

13. The method of claims 7, 9 and 12 wherein said commercial use may be sufficient to generate sufficient revenue to offset a portion of the cost of said desalination, said irrigation and said planting of vegetation.

14. The method of claims 9 and 12, wherein the portion of vegetation not converted to commercial use may be composted within said desert.

15. The method of claim 14, wherein said compost enriches desert soil.

16. The method of claim 14 wherein said compost may be produced by an aerobic process, which in part produces the greenhouse gas CO.SUB.2 as a by-product.

17. The method of claim 14 wherein said compost may be produced by an anaerobic process which in part produces the greenhouse gas methane as a by-product.

18. The method of claims 11, 16 and 17 wherein the method of composting may be controlled to ensure the level of CO.SUB.2 sequestration exceeds the amount of greenhouse gas production.

19. The method of claims 7 and 9, wherein said vegetation sequesters a portion of the desalinated seawater pumped into the desert above the current level of water sequestration in said desert.

20. The method of claim 19 wherein said water moderates the day and nighttime temperature fluctuations of said desert environment.

21. The method of claims 7 and 20 wherein said moderated daytime temperature reduces the rate of evaporation of said desalinated water from said desert.

22. The method of claim 7 wherein said desalinated seawater pumped into said desert might otherwise contribute to sea level rises that could inundate coastal areas.

23. The method of claim 7, wherein said seawater may be desalinated by the process of;
a. reverse osmosis, and/or
b. ion exchange, and/or
c. distillation.

24. The method of claim 7 wherein the power required to pump and desalinate said seawater may be derived from either:
1) wind energy and/or,
2) Ocean Thermal Energy Conversion and/or,
3) solar thermal energy.
